(19) United States
(12) Patent Application Publication
(10) Pub. No.: US 2016/0324285 A1
(43) Pub. Date: Nov. 10, 2016

(54) Raez

(71) Applicant: Cesar R. Zavala, Fontana, CA (US)

(72) Inventor: Cesar R. Zavala, Fontana, CA (US)

(21) Appl. No.: 14/707,152

(22) Filed: May 8, 2015

(51) Int. Cl. A45C 11/00; H05K 5/03; A45C 11/32

(52) U.S. Cl. CPC A45C 11/00; A45C 11/321; H05K 5/03; A45C 2011/002

(57) ABSTRACT

This invention relates to a sleeved phone case by which a user may carry and operate a mobile communications device and one or more credit card sized items in a single pocket or multiple pockets case. A sleeved phone case with rear covering comprising: a main housing configuration to fit securely around electronic device; a back housing configure to fit at least cards, and or bills and or cash, and or electronic items.

### CROSS REFERENCE TO RELATED APPLICATIONS

Not applicable.

### FEDERALLY SPONSORED RESEARCH AND DEVELOPMENT

Not applicable.

### MICROFICHE

Not applicable

### BACKGROUND OF THE INVENTION

(1) Field of the Invention

The present invention relates to the field of protective covers or cases customized to fit handheld mobile communications devices such as cell phones and personal data assistants, including while these devices are in use The invention, particularly relates to protective sleeve type phone case coverings for enclosing a personal electronic device and one or more cards, such as credit cards, payment cards, coupons, receipts, identification cards, merchandise credit cards, gift cards, or business cards.

(2) Background of the Invention

In many countries, the majority of the population carries at least one handheld or otherwise the portable electronic device, such as a cell phone, a PDA (e.g., a Blackberry®, made by Research in Motion, Ltd., of Waterloo, Ontario, Canada, and/or an iPhone®, made by Apple, Inc., of Cupertino, Calif.), or similar device which carries both their personal and business data (hereinafter collectively and generically “PDAs” or “personal electronic devices”). There has been a trend towards combining several functions of different types within the same device so as to minimize pocket or purse clutter and to make the products more integrated, useful and convenient. There has also been a trend to shrink the size of PDAs to make them as portable as possible, preferably pocket-sized (meaning, able to fit within the average person's pants pocket comfortably).

However, if one is out and about with one's cell phone or PDA, one still must carry a wallet for one's cash, credit cards, train passes identification cards or badges, and the likes. The greater the number of such items a person carries around, the greater the likelihood that they will either forget one or more of the items at home, and the greater the likelihood that they will misplace one in a restaurant, bar, office, etc. Even were one not to lose or misplace anything, fumbling around looking for a wallet while holding a PDA or vice versa wastes time, is uncomfortable for the user, and reduces the “cool” factor of having a cutting edge PDA. There is a long-felt need to somehow make carrying a PDA even more convenient and efficient.

A number of different types of protective coverings are available for PDAs. For example, see: U.S. patent application Ser. No. 2007/0223183 to Oja; U.S. patent application Ser. No. 11/976,928 to Kevin; U.S. patent application Ser. No. 2007/0215663 to Chongson et al.; U.S. patent application Ser. No. 2002/0101411 to Chang; U.S. Pat. No. 8,047,364 B2 to Kip; Pat. No.6,892,880 to Nieves; Pat. No. 6,758,335 to Kajiya; Pat. No. 6,483,697 to Jenks at al.; Pat. No. 6,445,577 to Madsen at al.; Pat. No. 6,347,796 to Grossman at al.; Pat. No. 5,348,347 to Shink; or Pat. No. 5,006,699 to Felkner at al.

These conventional coverings tend to fall into four general categories: a soft covering or “skin” that hugs the contour of the PDA, made from a resilient material such as silicone rubber; hard shell cases made from plastic or metal; flip/folio-style coverings that provide an operable and closeable front cover over the PDA; and camera-case style bags that are usually soft, pliable, cushioned, and significantly larger than the PDA itself.

Each of these categories has its drawbacks. The first category, the “skin” covering, is quite popular, however, it serves only to cover the device; it cannot hold anything else.

The second category, hard clamshell-style cases, includes the above mentioned Change US patent application and the above mentioned Kajiya, Madsen, Jenks, and Kim et al, US patents. While these cases may protect the PDA inside, they must be fully opened in order to use the PDA. Also, these cases are not designed to hold anything but the PDA itself.

The third category is a flip folio-style cases; this category includes the above mentioned Oja US patent application and the above mentioned Nieves, Grossman, Shink, and Felkner US patents. As with the clamshell cases, a cover flips open and closed over the PDA, usually with a securing mechanism such as a snap, a magnet, or hook and loop fasteners (e.g., Velcro®). In order to use the PDA, the cover must be opened, thereby exposing the front of the device. This is inconvenient. Additionally, the presence of a flip-openable cover adds such a significant amount of bulk to the otherwise pocket-sized PDA so as to render it less convenient to carry. As an example, the Shink patent teaches a diaper-bag-like roll that has not one fold-over flap of a cover but four fold-over panels. Also, the majority of this style of case can only hold the PDA itself, although some, such as Felkner, Nieves, and Shink may have an internal pocket. By providing a pocket, internal to the case, the case must be opened in order to access the pocket. This is inconvenient, and risk injury to the PDA for the sake of accessing pocket.

Finally, the fourth category of camera-bag-style coverings includes the above mentioned Chongson et al. US patent application. This style likely offers the most protection (depending on the amount of cushioning provided), however, it is potentially the most dangerous and the least convenient. For one, not only cannot the user use the PDA when the bag is closed, the PDA must be wholly removed from the safety of the bag in order to be used. Thus, in order to use the PDA, the user must render the PDA complete susceptible to catastrophic damage (e.g., by dropping it). Moreover, the bag-style covering is so large as to render the PDA no longer so small to be convenient; for example, in Chongson, the bag is so large, the user must wear the bag with the PDA inside. It is no longer pocket-sized, and thus unacceptable for many users; one may as well carry a backpack or a suitcase.

Thus, there is a long-felt need to provide a cover that protects the device, and makes the device more convenient and efficient, while keeping true to the pocket-sized portable and personal nature of a PDA. Therefore, in this way this invention provides a sleeve phone case that fits over the phone and other items go behind the face of the phone where they are not seen.

### SUMMARY OF THE INVENTION

In the view of the foregoing disadvantages inherent in the known types of protective covering now present in the prior art, the present invention Raez provides an improved protective covering. As such, the general purpose of the present invention, which will be described subsequently in greater detail, is to provide a new and improved sleeve phone case which has all the advantages of the prior art and none of the disadvantages.

An object of the invention is to provide a sleeved phone case by which a user may carry and operate a mobile communications device and one or more credit card sized items in a single or multiple pockets or compartments on the case cover.

It is another object of the present invention to provide sleeved phone case that allows the consumers to hold electronic items such as car keys and headphones.

It is another object of the present invention to provide sleeved phone case includes a front and a back in which elastic pocket is fixed on back and it is stretchable to accommodate different items like, car keys, headphones etc.

It is another object of the present invention to provide sleeved phone case which is going over any existing case to carry any personal item nicely.

It is another object of the present invention to provide sleeved phone case which is available in comes in various sizes to fit any type of cell phone.

It is another object of the present invention to provide sleeved phone case which is easily fit into the pocket.

It is another object of the present invention to provide sleeved phone case which is to carry and expensive on marketing.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

These together with other objects of the invention, along with the various features of novelty which characterize the invention, are pointed out with particularity in the disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF THE DRAWINGS

The invention will be better understood and objects other than those set forth above will become apparent when consideration is given to the following detailed description thereof. Such description makes reference to the annexed drawings wherein:

FIG. 1 depicts an isometric view of the Raez;

FIG. 2 depicts a front view of the Raez;

FIG. 3 depicts a back view of the Raez;

FIG. 4 depicts a right side of the Raez;

FIG. 5 depicts a left side view of the Raez;

FIG. 6 depicts a top view of the Raez; and

FIG. 7 depicts a bottom view of the Raez,

### DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. The following detailed description is, therefore, not to be taken in a limiting sense, and the scope of the present invention is defined by the appended claims and their equivalents.

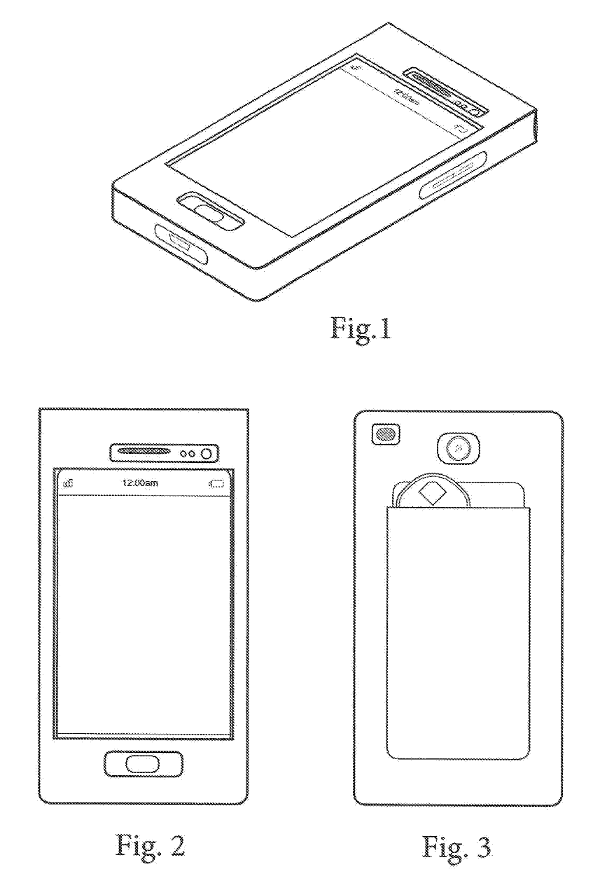

On referring FIG. 1 show the phone sleeve casing holding a cell phone. The covering surrounds at least most of the electronic device, e.g., the back, the sides, the top and bottom and leaves the front of the device exposed, i.e., has a front window, which allows the user to access keyboard/touchscreen and see displays in a normal manner. Also, front portion of the cover providing the space which is require exposing general features of cell phone like front camera, sensor, access button etc.

As best illustrated in the sectional views of FIG. 1 shows a front view of protective case. Covering may also have holes on one or more sides, the top, the back, or bottom locations allow the user to access any buttons, camera lenses, or the like that may be provided with cell phones. Each different model or make of cell phones will preferably have a corresponding covering that has the appropriate overall shape as well as holes that correspond to the relevant buttons and features.

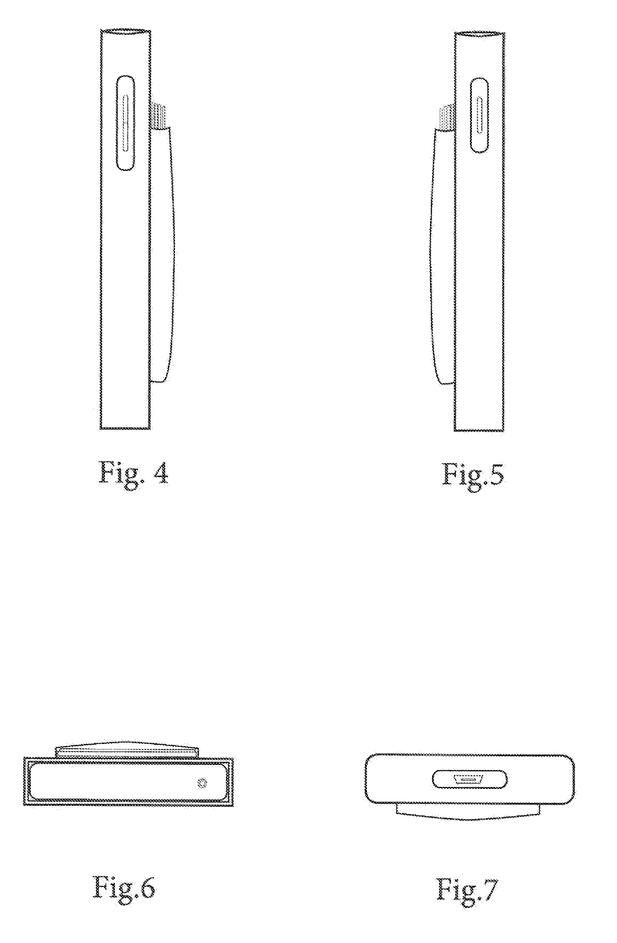

On referring FIG. 3-5 show the phone sleeve casing which holds debit cards, credit cards along with other items such as car keys and headphones and cell phone. The Phone sleeve casing covers the top and bottom part of a phone FIGS. 6 and 7. Also, on the rear portion of cover having space above sleeve casing which exposes the camera part of cell phone. The Cell Phone Wallet Sleeve is removable, to be used on its own as a wallet. The ID and bank cards are also kept out of view behind the phone's screen when in use.

The Phone Sleeve Casing comes in various sizes to fit any type of Cell phone as shown in FIG. 1. It can be made in different colors, and materials. Preferably it is made up of elastic/polifibers and wet suit material.

The covering sleeve doesn't interfere with phone, or hand holding the phone. It's small enough not to be noticeable, and it replaces the cumbersome wallet.

The Phone Sleeve Casing is great because it doesn't interfere with the phone's buttons or features and allow consumers to hold other items such as car keys and headphones. And it's easy to slide on and off. Slide on, have all your ID and money available. Slide off and keep a handy wallet with your ID and Debit cards.

The way to make, it would be to stitch the materials together following the details of the drawing. All the materials, plastic, wetsuit material, etc., would be stitched together exactly like a wallet would.

Advantageously, the present invention is different from the existing prior art. Prior cover involves strapping, buckles, latches and covers the entire phone. They make the cell phone bulky, awkward, and hard to carry. Other inventions require buttons and flaps to access Bank Cards. However, with the phone sleeve casing, anyone can reach into the top of the wallet any time and remove their bank cards and other above mentioned items.

It is to be understood that the above description is intended to be illustrative, and not restrictive. For example, the above-discussed embodiments may be used in combination with each other. Many other embodiments will be apparent to those of skill in the art upon reviewing the above description.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the embodiments.

While the present invention has been described with reference to particular embodiments, it should be understood that the embodiments are illustrative and that the scope of the invention is not limited to these embodiments. Many variations, modifications, additions and improvements to the embodiments described above are possible, It is contemplated that these variations, modifications, additions and improvements fall within the scope of the invention.

I claim:

1. A sleeved phone case with rear covering comprising:
a main housing configuration to fit securely around electronic device; and
a back housing configure to fit at least cards, and or bills and or cash, and or electronic items.

2. A sleeved phone case with rear covering according to claim 1, wherein main housing and back housing attached to each other.

3. A sleeved phone case with rear covering according to claim 1, in which said covering is made up of combination of stretchable material.

4. A sleeved phone case with rear covering according to claim 1, wherein combination includes wetsuit plastic material.

5. A sleeved phone case with rear covering according to claim 1, wherein said case is stretchable to fit with any phone.

6. A sleeved phone case with rear covering according to claim 1, wherein said electronic items include car keys, and or headphones.

7. A sleeved phone case with rear covering according to claim 1, wherein said case partially covers the cell phone screen.
